(19) United States
(12) Patent Application Publication
(10) Pub. No.: US 2025/0218931 A1
(43) Pub. Date: Jul. 3, 2025

(54) INTERCONNECT VIA WITH INDUCED ASYMMETRIC PROFILE

(71) Applicant: Intel Corporation, Santa Clara, CA (US)

(72) Inventors: Angelo W. Kandas, Portland, OR (US); Codi A. Sanders, Hillsboro, OR (US); Mansi Seth, Portland, OR (US); Jessica A. Parker; Ameen Sayal, Hillsboro, OR (US); Mark Koeper, Beaverton, OR (US); Nicholas J. Kybert, Portland, OR (US)

(73) Assignee: Intel Corporation, Santa Clara, CA (US)

(21) Appl. No.: 18/399,217

(22) Filed: Dec. 28, 2023

(51) Int. Cl. H01L 23/522; H01L 21/768; H01L 21/8234; H01L 23/528; H01L 27/088

(52) U.S. Cl. CPC H01L 23/5226; H01L 21/76816; H01L 23/5283; H10D 84/0149; H10D 84/038; H10D 84/83

(57) ABSTRACT

Techniques are provided herein for forming a via with an asymmetrically flared profile within the interconnect region over semiconductor devices. In some examples, a via within the interconnect layer has a greater critical dimension (CD), or top surface width, along a first direction (e.g., along an X-axis) than it has along a second direction orthogonal to the first direction (e.g., along a Y-axis). The bottom surface of the via may have substantially the same width along both the first and second directions, such that the width of the via tapers or steps inward between the top surface width along the first direction and the bottom surface width along the first direction. There is little to no tapering or step of the via between the top surface width along the second direction and the bottom surface width along the second direction.

### BACKGROUND

As integrated circuits continue to scale downward in size, a number of challenges arise. For example, interconnect structures also scale smaller as devices become more densely packed on a chip. For some structures, such as vias, the small size can lead to a higher than desired resistance. Accordingly, there remain a number of non-trivial challenges with respect to designing and fabricating interconnect structures.

### BRIEF DESCRIPTION OF THE DRAWINGS

FIG. 1 is a cross-sectional view that illustrates an example portion of an integrated circuit configured with an interconnect region over a plurality of semiconductor devices, in accordance with an embodiment of the present disclosure.

FIGS. 2A and 2B are cross-sectional views, orthogonal with respect to each other, of an interconnect via having an asymmetrically flared profile, in accordance with an embodiment of the present disclosure.

FIGS. 2A′ and 2B′ are cross-sectional views, orthogonal with respect to each other, of an interconnect via having an asymmetrically flared profile, in accordance with another embodiment of the present disclosure.

FIGS. 3A and 3B are cross-sectional views, orthogonal with respect to each other, that illustrate one stage in an example process for forming an integrated circuit configured with one or more vias having an asymmetrically flared profile, in accordance with an embodiment of the present disclosure.

FIGS. 4A and 4B are cross-sectional views, orthogonal with respect to each other, that illustrate another stage in the example process for forming an integrated circuit configured with one or more vias having an asymmetrically flared profile, in accordance with an embodiment of the present disclosure.

FIGS. 5A and 5B are cross-sectional views, orthogonal with respect to each other, that illustrate another stage in the example process for forming an integrated circuit configured with one or more vias having an asymmetrically flared profile, in accordance with an embodiment of the present disclosure.

FIGS. 6A and 6B are cross-sectional views, orthogonal with respect to each other, that illustrate another stage in the example process for forming an integrated circuit configured with one or more vias having an asymmetrically flared profile, in accordance with an embodiment of the present disclosure.

FIGS. 7A and 7B are cross-sectional views, orthogonal with respect to each other, that illustrate another stage in the example process for forming an integrated circuit configured with one or more vias having an asymmetrically flared profile, in accordance with an embodiment of the present disclosure.

FIGS. 8A and 8B are cross-sectional views, orthogonal with respect to each other, that illustrate another stage in the example process for forming an integrated circuit configured with one or more vias having an asymmetrically flared profile, in accordance with an embodiment of the present disclosure.

FIG. 9 is a cross-sectional view of an asymmetrically flared via within a portion of an interconnect region between two metal lines, in accordance with an embodiment of the present disclosure.

FIG. 10 illustrates a cross-section view of a chip package containing one or more semiconductor dies, in accordance with an embodiment of the present disclosure.

FIG. 11 is a flowchart of a fabrication process for an integrated circuit including one or more vias having an asymmetrically flared profile, in accordance with an embodiment of the present disclosure.

FIG. 12 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein for forming a via with an asymmetrically flared profile within the interconnect region over a device layer. The interconnect region may include any number of interconnect layers (dielectric material with conductive interconnect features such as lines and vias), and the device layer may include, for example, a plurality of field effect transistor (FET) devices. Although the techniques can be used in any number of integrated circuit applications, they are particularly useful with respect to forming interconnects for size-constrained transistors such as those used in logic and memory cells. In some such examples, a via within a given interconnect layer is elongated, in that it has a greater critical dimension (CD), or top surface width, along a first direction (e.g., along an X-axis) than it does along a second direction orthogonal to the first direction (e.g., along a Y-axis). The bottom surface of the via may have substantially the same width along both the first and second directions, such that the width of the via tapers or steps between the top surface width along the first direction and the bottom surface width along the first direction. There may be little to no step or tapering of the via between the top surface width along the second direction and the bottom surface width along the second direction. Such an asymmetrically tapered or stepped via provides a greater contact area to a higher metal line (or other higher interconnect feature) while maintaining a smaller contact area to a lower metal line (or other lower interconnect feature), which can lower resistance while still allowing for tightly packed vias. Numerous variations and embodiments will be apparent in light of this disclosure.

### General Overview

As previously noted above, it can be challenging to densely pack as many transistors as possible on a chip. One limitation is the ability to provide interconnects to all of the various transistor structures of an underlying device layer. Interconnect structures, such as vias and metal lines, may be formed using either a dual damascene or single damascene process. In a dual damascene process, the via recess is formed along with a metal line recess, such that the via and metal line can be formed together within a given interconnect layer or across two interconnect layers. In a single damascene process, a via is formed independently of the metal line through an interconnect layer. The dual damascene process can produce via connections with a relatively lower resistance, but is limited in how closely packed the vias can be. On the other hand, densely packed vias can be formed using the single damascene process, but the straight or nearly straight sidewalls yield very narrow structures that exhibit a relatively higher resistance.

Thus, techniques are provided herein for forming asymmetric vias that exhibit a relatively lower resistance compared to symmetric vias. The techniques can be used in any number of process schemes, and are particularly useful to leverage the advantages of the single damascene process while minimizing the drawbacks. The techniques can be used in any number of applications that utilize interconnect structures to route signals and/or power rails over (or under, as the case may be) semiconductor devices. According to some embodiments, a via extends through a given interconnect layer with an asymmetrically flared profile with a top surface that extends further in one direction than it does in the orthogonal direction. However, the bottom surface of the via remains substantially equal in width (e.g., within 10 angstroms of one another) along both directions, providing a via with a higher top surface area compared to its bottom surface area. The flared via design may be formed, for example, by directionally etching portions of a mask structure around a via recess, such that more of the mask structure is removed along the first direction adjacent to the opening compared to the volume of mask structure removed along the second direction adjacent to the opening. An additional etch may then be performed to widen the via opening further across the first direction compared to the second direction while the sidewalls of the via opening flare outward further along the first direction compared to the second direction.

According to an embodiment, an integrated circuit includes a plurality of semiconductor devices, an interconnect region above the plurality of semiconductor devices having a plurality of interconnect layers, and a via structure within an interconnect layer of the plurality of interconnect layers. The via structure has a first dimension across a top surface of the via structure along a first direction and a second dimension across the top surface of the via structure along a second direction orthogonal to the first direction. In some such examples, the first dimension is greater than the second dimension by at least 4 nm or 5 nm. The via structure also has a third dimension across a bottom surface of the via structure along the first direction and a fourth dimension across the bottom surface of the via structure along the second direction. In some such examples, the third dimension is within 1 nm of the fourth dimension. Other examples may be configured differently to provide other geometries, but still provide an asymmetric via that allows for lower contact resistance.

According to another embodiment, an integrated circuit includes an interconnect region above a plurality of semiconductor devices with the interconnect region having a plurality of interconnect layers, and an interconnect layer of the plurality of interconnect layers. The interconnect layer includes a dielectric layer and a via passing through the dielectric layer. The via has a first dimension across a top surface of the via along a first direction and a second dimension across the top surface of the via along a second direction orthogonal to the first direction. The first dimension is greater than the second dimension by at least 4 nm or 5 nm. The via also has a third dimension across a bottom surface of the via along the first direction and a fourth dimension across the bottom surface of the via along the second direction. The third dimension is within 1 nm of the fourth dimension.

According to another embodiment, a method of forming an integrated circuit includes forming an interconnect layer above a plurality of semiconductor devices. Forming the interconnect layer includes forming a dielectric layer, forming an opening through the dielectric layer, and forming a conductive via within the opening. Forming the opening includes forming a mask material on the dielectric layer, etching a first opening through the mask material, etching a second opening through the dielectric layer beneath the first opening, directionally etching the mask material to remove portions of the mask material along opposing edges of the opening through the dielectric layer, etching exposed portions of the dielectric layer beneath the removed portions of the mask material, and removing any remaining portion of the mask material.

The techniques can be used to form interconnect structures for any type of planar and non-planar transistors, including finFETs (sometimes called double-gate transistors, or tri-gate transistors), nanowire and nanoribbon transistors (sometimes called gate-all-around transistors), and thin film transistors, to name a few examples. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a remove metal gate, or RMG, process). Any number of semiconductor materials can be used in forming the transistors such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate conductive vias or contacts within the interconnect region have an asymmetrically flared profile. The CD along the top surface of the via may be longer (e.g., at least 4 nm, at least 5 nm, at least 10 nm, at least 15 nm, or at least 20 nm longer) in one direction than it is in an orthogonal direction across the plane of the top surface. Additionally, the sidewalls are flared inwards, with a gradual taper or a more abrupt step, such that the bottom surface CD is substantially the same across the two orthogonal directions.

The meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer.

### Architecture

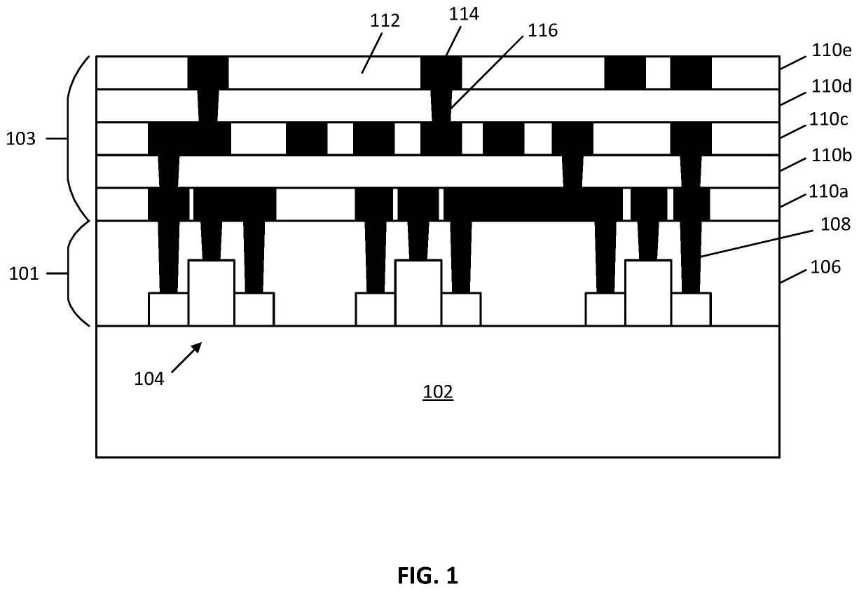

FIG. 1 is a cross-sectional view that illustrates an example portion of an integrated circuit having an interconnect region above a plurality of semiconductor devices, in accordance with an embodiment of the present disclosure. The semiconductor devices in this example are non-planar metal oxide semiconductor (MOS) transistors, such as tri-gate or gate-all-around (GAA) transistors, although other transistor topologies and types can also benefit from the techniques provided herein, as will be appreciated (e.g., planar transistors, thin film transistors, or any other transistors to which contact can be made).

According to some embodiments, the integrated circuit includes a device region 101, and an interconnect region 103 over the device region 101. Device region 101 may include a plurality of semiconductor devices 104 along with one or more other layers or structures associated with the semiconductor devices 104. For example, device region 101 can also include a substrate 102 and one or more dielectric layers 106 that surround active portions or contacts of the semiconductor devices 104. Device region 101 may also include one or more conductive contacts 108 that provide electrical contact to transistor elements such as gate structures, drain regions, or source regions. Conductive contacts 108 include, for example, tungsten, although other metal or metal alloy materials may be used as well. Conductive contacts may also be a part of, or otherwise include, what is sometimes called a local interconnect, which is considered part of the device layer and usually formed prior to any backend processing.

Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, backside processing is used to remove substrate 102 and form any number of backside interconnect layers.

Interconnect region 103 includes a plurality of interconnect layers 110a-110e stacked over one another. Each interconnect layer can include a dielectric material 112 along with one or more different conductive features. Dielectric material 112 can be any dielectric, such as silicon oxide, silicon oxycarbide, silicon nitride, or silicon oxynitride. Dielectric material 112 may be deposited using any known dielectric deposition technique such as chemical vapor deposition (CVD), plasma-enhanced chemical vapor deposition (PECVD), flowable CVD, spin-on dielectric, or atomic layer deposition (ALD). The one or more conductive features can include conductive traces 114 and conductive vias 116 arranged in any pattern across the interconnect layers 110a-110e to carry signal and/or power voltages to/from the various semiconductor devices 104. A conducive via, such as conductive via 116, may extend through an interconnect layer to connect between conductive traces on an upper interconnect layer and a lower interconnect layer. In other cases, a via 116 may only extend part way through a given interconnect layer. Although interconnect region 103 is illustrated with only five interconnect layers, any number of interconnect layers can be used within interconnect region 103. Also, this example shows vias and lines in different interconnect layers, in both single and dual damascene configurations. In other examples, vias and lines may also exist within the same interconnect layer, such as in the case of some dual damascene configurations.

Any of conductive traces 114 and conductive vias 116 can include any number of conductive materials, with some examples including copper, ruthenium, tungsten, cobalt, molybdenum, and alloys thereof. In some cases, any of conductive traces 114 and conductive vias 116 include a relatively thin conductive liner or barrier, such as titanium nitride, titanium silicide, tungsten carbo-nitride (WCN), PVD or ALD tungsten, or tantalum nitride. As will be discussed in more detail herein, any of conductive vias 116 may have an asymmetrically flared profile that is wider in one direction compared to an orthogonal direction.

It should be noted that each of the various conductive vias 116 and conductive contacts 108 are shown with tapered profiles to indicate a more natural appearance due to the etching process used to form the openings. Any degree of tapering may be observed depending on the etch parameters used and the thickness of the dielectric layer being etched through. Furthermore, conductive vias may be stacked one over the other through different dielectric layers of interconnect region 103. However, in some examples, a single via recess may be formed through more than one dielectric layer yielding a taller, more tapered conductive via that extends through two or more dielectric layers. In other examples, such natural tapering may not be present.

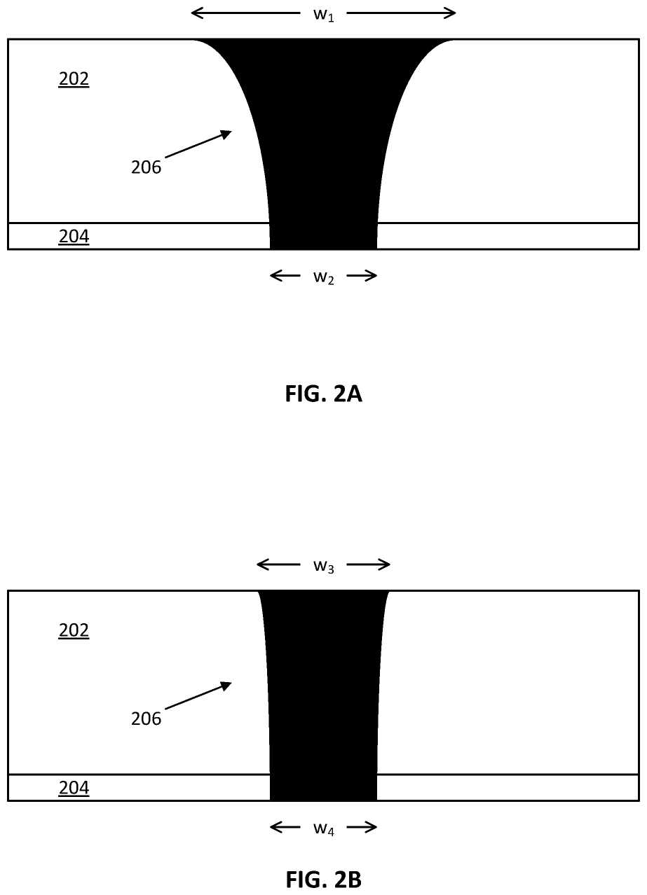

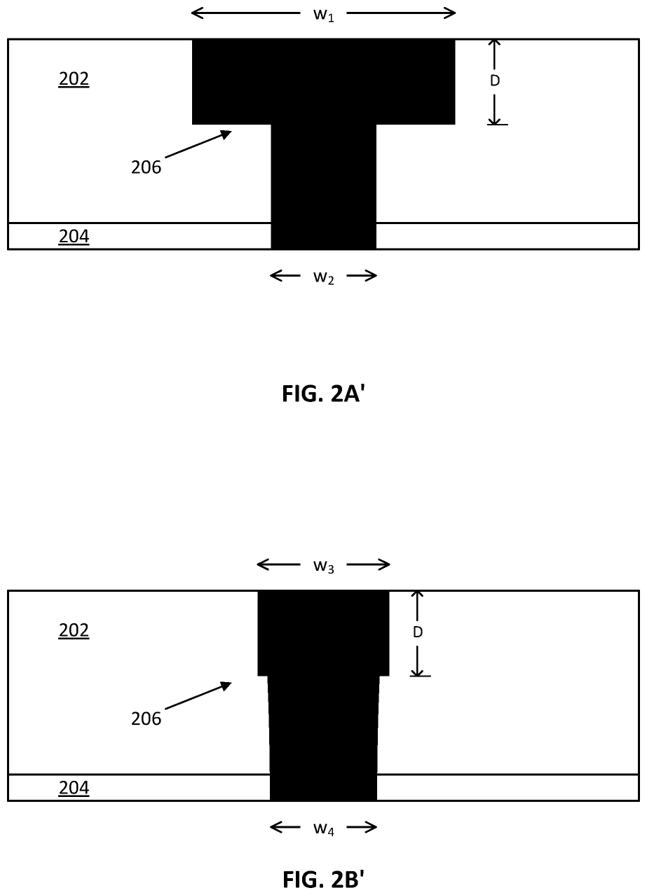

FIGS. 2A and 2B illustrate cross-sectional views of an interconnect layer (such as any one of interconnect layers 110a-110e) across a first direction or X-direction (FIG. 2A, left to right of page) and across a second direction or Y-direction orthogonal to the first direction (FIG. 2B, left to right of page). The Z-direction (top to bottom of page) is the same for both FIGS. 2A and 2B. According to some embodiments, the interconnect layer may include a dielectric layer 202, an etch stop layer 204, and a conductive via 206.

Dielectric layer 202 may be substantially similar to dielectric material 112 discussed above. Accordingly, dielectric layer 202 may be any suitable interconnect dielectric, such as silicon dioxide. Etch stop layer 204 may be provided between adjacent interconnect layers to protect underlying layers during etching processes on the layer above them. In the illustrated embodiment, etch stop layer 204 is provided as the lowest layer of a given interconnect layer, but it may also be the top layer of a given interconnect layer depending on where segmentation between interconnect layers is made. Etch stop layer 204 can be any suitable material that provides etch selectively to the dielectric material of dielectric layer 202. In some examples, etch stop layer 204 includes silicon nitride, silicon carbide, or silicon carbonitride.

According to some embodiments, via 206 includes a tapered profile with a longer flared taper along the first direction (FIG. 2A) compared to the second direction (FIG. 2B). Across the first direction, via 206 has a topside width w₁ and a bottom-side width w₂, and across the second direction, via 206 has a topside width w₃ and a bottom-side width w₄. According to some embodiments, topside width w₁ is greater than topside width w₃ while bottom-side width w₂ is substantially the same as bottom-side width w₄ (e.g., within 1 nm). This yields a tapered via profile across the first direction that flares outward more than the tapered profile across the second direction. In some embodiments, the sidewalls of via 206 across the second direction profile are substantially straight such that there is no visible taper across the second direction profile, and topside width w₃ is substantially the same as bottom-side width w₄ (e.g., within 1 nm). In some embodiments, a slight taper is observed across the second direction profile, such that the topside width w₃ is 1-3 nm greater than bottom-side width w₄.

According to some embodiments, topside width w₁ is at least 4 nm, 5 nm, at least 10 nm, at least 15 nm, or at least 20 nm greater than bottom-side width w₂. Bottom-side width w₂ may be between about 10 nm and about 20 nm. In some examples, via 206 may have an aspect ratio (height:width) that is substantially around 1:1, with a height that is between about 10 nm and about 15 nm. In other examples, via 206 may have an aspect ratio that is higher, such as 2:1, or 3:1, or higher. In other examples, via 206 may have an aspect ratio that is lower, such as 1:2, or lower.

According to some embodiments, via 206 includes any suitable conductive material that can be used as an interconnect material. For example, via 206 can include any number of conductive materials, with some examples including copper, ruthenium, tungsten, cobalt, molybdenum, and alloys thereof. In some cases, via 206 includes a relatively thin liner or barrier, such as titanium nitride, titanium silicide, tungsten carbo-nitride (WCN), PVD or ALD tungsten, or tantalum nitride.

The degree of induced flaring can vary from one example to the next, and in some cases is more abrupt, so as to provide a step-like transition rather than a gradual taper, such as shown in the examples of FIGS. 2A′ and 2B′. In such an example, via 206 includes a more abrupt or stepped profile with a longer step along the first direction (FIG. 2A′) compared to the second direction (FIG. 2B′). The above description with respect to widths w₁, w₂, w₃, and w₄ is equally application here. The distance D from the top of via 206 at which the step occurs can vary, for instance, depending on etch time, as further described below. As shown, a stepped via profile across the first direction extends outward more than the stepped profile across the second direction. In this particular example, a relatively small or slight step is observed across the second direction profile, such that the topside width w₃ is 1-3 nm greater than bottom-side width w₄. In still other examples, the sidewalls of via 206 across the second direction profile are substantially straight such that there is no visible step across the second direction profile, and topside width w₃ is substantially the same as bottom-side width w₄ (e.g., within 1 nm), or width w₃ subtly tapers inward to width w₄. The horizontal portion of the step may also be sloped or tapered or other than perfectly horizontal.

### Fabrication Methodology

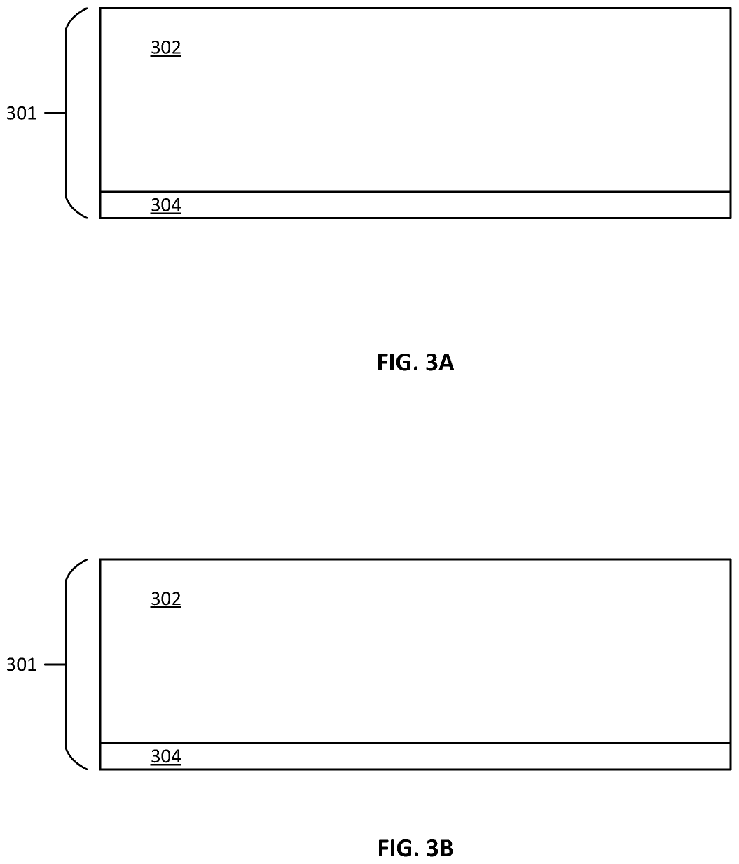

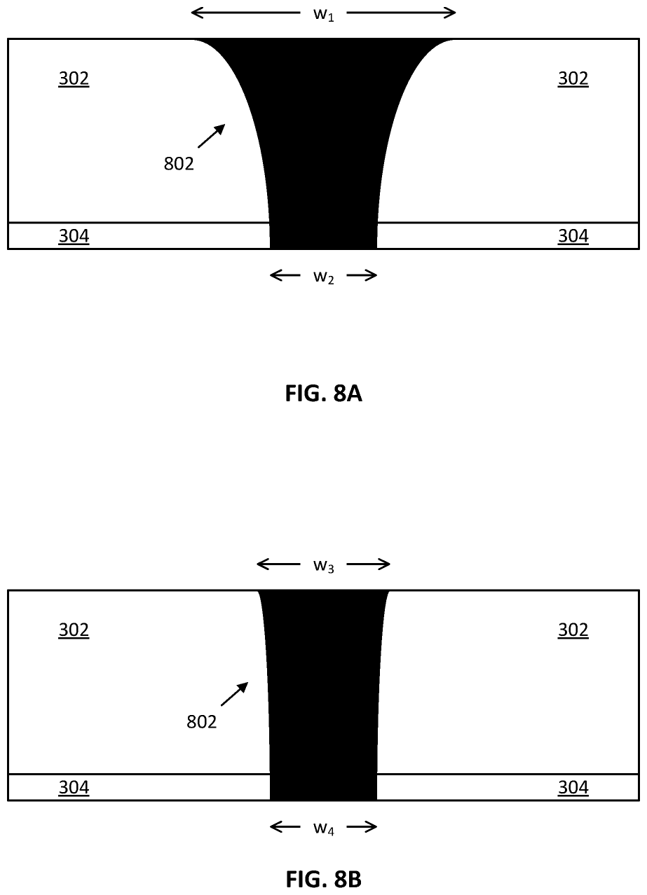

FIGS. 3A-8A and 3B-8B include cross-sectional views that collectively illustrate an example process for forming an integrated circuit having a via with an asymmetrically flared profile, in accordance with an embodiment of the present disclosure. FIGS. 3A-8A represent cross-sectional views taken across a first direction (e.g., an X-direction, left to right of page), while FIGS. 3B-8B represent cross-sectional views taken across a second direction (e.g., a Y-direction, left to right of page). Each set of figures sharing the same letter shows an example structure that results from the process flow up to that point in time, so the depicted structure evolves as the process flow continues, culminating in the structures shown in FIGS. 8A and 8B, which is similar to the structures shown in FIGS. 2A and 2B, respectively. Such structures may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated. The process described herein in FIGS. 3-8 may be repeated any number of times across any number of interconnect layers to form any number of vias having an asymmetrically flared profile.

FIGS. 3A and 3B are cross sectional views taken through a given interconnect layer 301 of a plurality of interconnect layers. Accordingly, the illustrated interconnect layer 301 may be at any position within interconnect region 103. Interconnect layer 301 includes a dielectric layer 302 that may be any dielectric material, such as silicon oxide, silicon oxynitride, silicon nitride, or silicon oxycarbide, and an etch-stop layer 304, according to some embodiments. Etch stop layer 304 may include another dielectric material that is different from the dielectric material of dielectric layer 302. For example, etch-stop layer 304 may include silicon nitride, silicon carbide, or silicon carbonitride. Each of dielectric layer 302 and etch-stop layer 304 may be deposited using any known dielectric deposition technique, such as CVD, PECVD, flowable CVD, spin-on dielectric, or ALD. Interconnect layer 301 may have a total height between about 10 nm and about 20 nm.

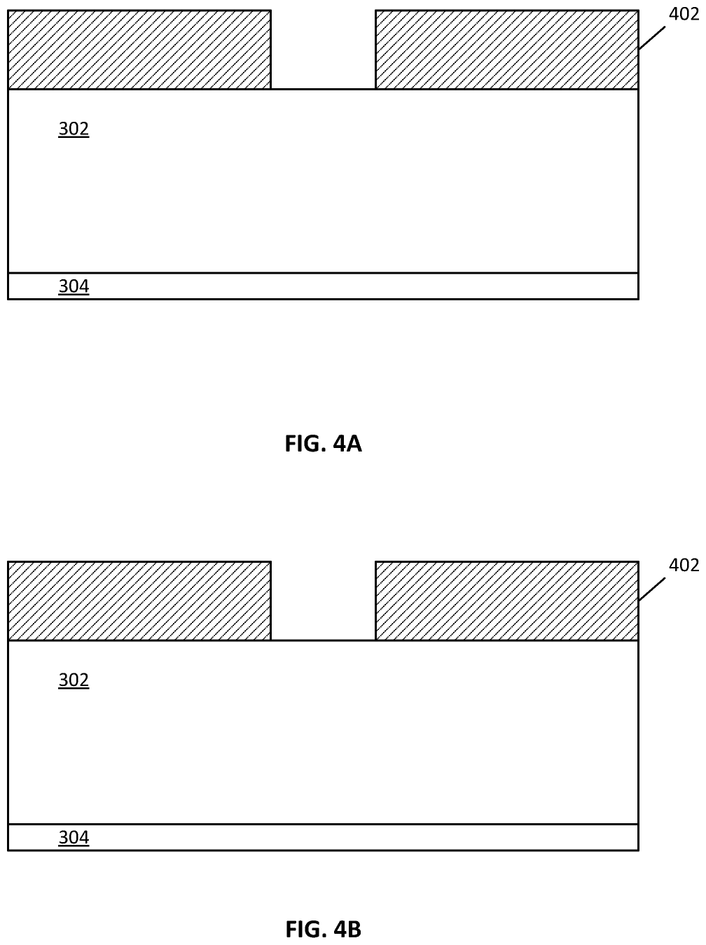

FIGS. 4A and 4B are cross sectional views taken through the given interconnect layer 301 of FIGS. 3A and 3B following the formation and patterning of a mask structure 402, according to some embodiments. Mask structure 402 includes a masking material that can be easily removed without damaging lower material layers, and can be easily shaped using directional anisotropic etching. In some embodiments, mask structure 402 includes carbon hard mask (CHM). Any suitable lithography process can be used with photoresist to etch an opening through mask structure 402. The etching process may use an anisotropic etching technique, such as reactive ion etching (RIE). The opening designates the location for the via that will extend through a height of dielectric layer 302. Note that the size of the opening is substantially the same across the first direction and the second direction. The opening width may be between about 10 nm and about 20 nm.

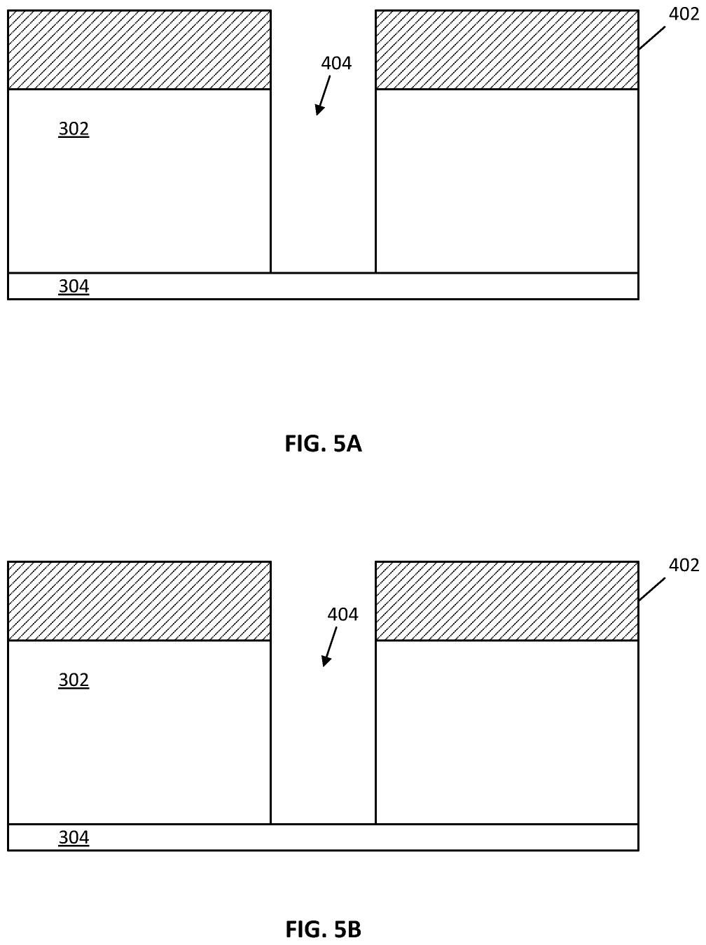

FIGS. 5A and 5B are cross sectional views taken through the given interconnect layer 301 of FIGS. 4A and 4B following the formation of a via recess 404 through dielectric layer 302, according to some embodiments. Via recess 404 may extend through an entire thickness of dielectric layer 302 and stop along a top surface of etch-stop layer 304. Via recess 404 may be formed using any anisotropic etching technique, such as RIE, while the unetched regions of dielectric layer 302 are masked by mask structure 402. According to some embodiments, via recess 404 has substantially straight sidewalls across both profiles in the first and second directions.

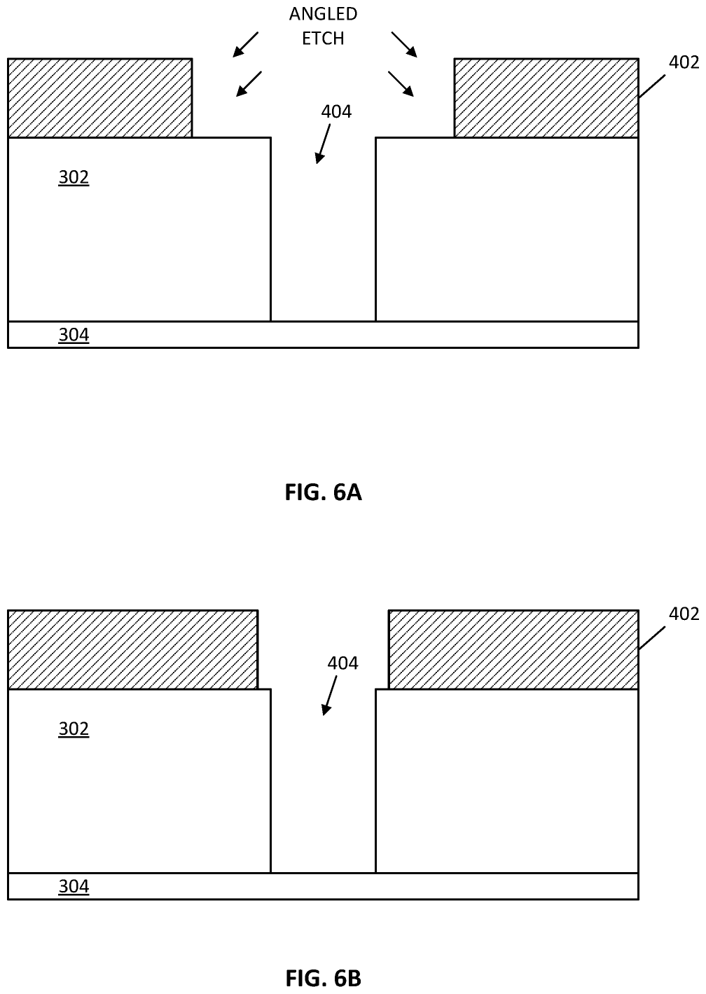

During a normal single damascene via process, a conductive material would be formed within via recess 404 to complete the formation of the via. However, according to some embodiments of the present disclosure, via recess 404 is asymmetrically widened with a flared profile. FIGS. 6A and 6B are cross sectional views taken through the given interconnect layer 301 of FIGS. 5A and 5B following a directional etching process to etch back portions of mask structure 402 from around via recess 404, according to some embodiments. In an example, a directional RIE process may be used with an oxygen-rich ion beam to angle the ions such that mask structure 402 is preferentially etched more aggressively along the first direction than along the second direction. As a result, mask structure 402 is pulled further back from via recess 404 along the first direction (FIG. 6A) than it is along the second direction (FIG. 6B). In some embodiments, mask structure 402 is pulled away from via recess 404 along the first direction by between 2 to 15 nm on each side of via recess 404. Due to the directionality of the etching process, mask structure 402 may remain at the edge of via recess 404 along the second direction, or may be pulled back a substantially smaller amount, such as less than 2 nm or less than 1 nm on each side of via recess 404.

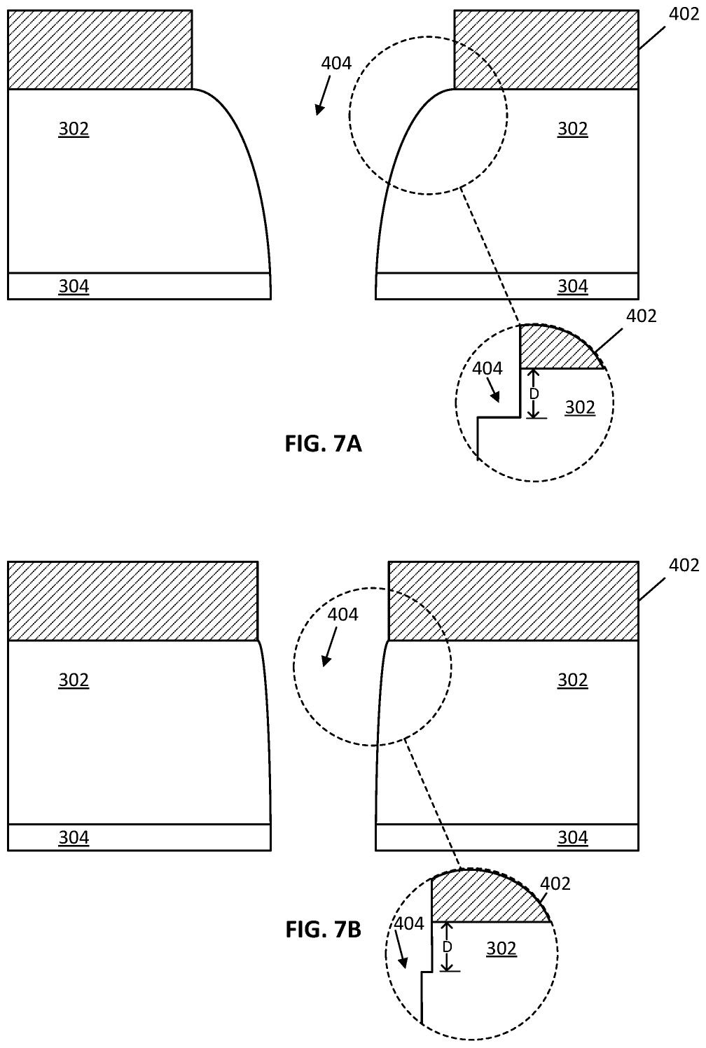

FIGS. 7A and 7B are cross sectional views taken through the given interconnect layer 301 of FIGS. 6A and 6B following another anisotropic etching process to widen via recess 404 further along the first direction compared to the second direction, according to some embodiments. An RIE process may be performed to etch both the exposed dielectric layer 302 and the exposed etch-stop layer 304 at the bottom of via recess 404. In some examples, the vertical etch rounds off the exposed corners of dielectric layer 302 and forms tapered or flared sidewalls for via recess 404. According to some such embodiments, the sidewalls flare outward further along the first direction then they do along the second direction. The degree of taper may vary depending on the parameters of the RIE process, and in other examples the transition is more of an abrupt step rather than a gradual taper (as shown in the dashed pull-outs), but in any case, the top of via recess 404 is wider along the first direction compared to the second direction while the bottom of via recess 404 has substantially the same dimension across the first direction and the second direction. The duration and directionality of the etch can be tuned to provide a desired taper or step profile. The geometry of the opening in mask structure 402, the depth of recess 404, and the etch rate of the dielectric material of layer 302 may also contribute to the transition profile. For instance, a vertical anisotropic etch for a given duration may create a more abrupt step profile, while an angled anisotropic etch or a combinational vertical and angled anisotropic etch may create a more tapered or sloped profile. In either case, the duration of the etch can be set, for example, to provide the step at a distance D from the top of dielectric layer 302, or to provide an inward taper as shown. In any such cases, the top of via recess 404 is wider along the first direction compared to the second direction while the bottom of via recess 404 has substantially the same dimension across the first direction and the second direction, so as to provide an asymmetric via shape.

FIGS. 8A and 8B are cross sectional views taken through the given interconnect layer 301 of FIGS. 7A and 7B following the removal of mask structure 402 and formation of conductive via 802 within via recess 404, according to some embodiments. Mask structure 402 may be removed using any suitable isotropic etching process or ashing process.

Conductive via 802 may be formed by depositing one or more conductive materials using any one of electroplating, electroless plating, CVD, or PECVD, to name a few examples. Conductive via 802 may include any suitable metal material such as copper, tungsten, ruthenium, cobalt, molybdenum, or aluminum to name a few examples. In some embodiments, conductive via 802 includes a thin conductive liner or barrier deposited first on the recess sidewalls and recess bottom followed by a metal fill on the liner or barrier. The conductive liner may include suitable metals or compounds such as titanium nitride, titanium silicide, tungsten carbo-nitride (WCN), PVD or ALD tungsten, or tantalum nitride. In some examples, the conductive liner may have a thickness between about 2 and 5 nm.

According to some embodiments, conductive via 802 includes an asymmetrically tapered profile with a longer flared taper along the first direction (FIG. 8A) compared to the second direction (FIG. 8B). Across the first direction, conductive via 802 has a topside width w₁ and a bottom-side width w₂, and across the second direction, conductive via 802 has a topside width w₃ and a bottom-side width w₄. According to some embodiments, topside width w₁ is greater than topside width w₃ while bottom-side width w₂ is substantially the same as bottom-side width w₄ (e.g., within 1 nm). In some embodiments, the sidewalls of conductive via 802 across the second direction profile are substantially straight such that there is no visible taper across the second direction profile, and topside width w₃ is substantially the same as bottom-side width w₄ (e.g., within 1 nm). In some embodiments, a slight taper is observed across the second direction profile, such that the topside width w₃ is 1-3 nm greater than bottom-side width w₄. As described above, other examples may include a more abrupt step or flare, rather than a gradual taper or flaring, but nonetheless provide an asymmetric via. According to some embodiments, topside width w₁ is at least 4 nm, 5 nm, at least 10 nm, at least 15 nm, or at least 20 nm greater than bottom-side width w₂, and bottom-side width w₂ may be between about 10 nm and about 20 nm. Via 206 may have an aspect ratio that is substantially around 1:1, with a height that is between about 10 nm and about 15 nm. In other examples, the aspect ratio may be higher or lower, as described above.

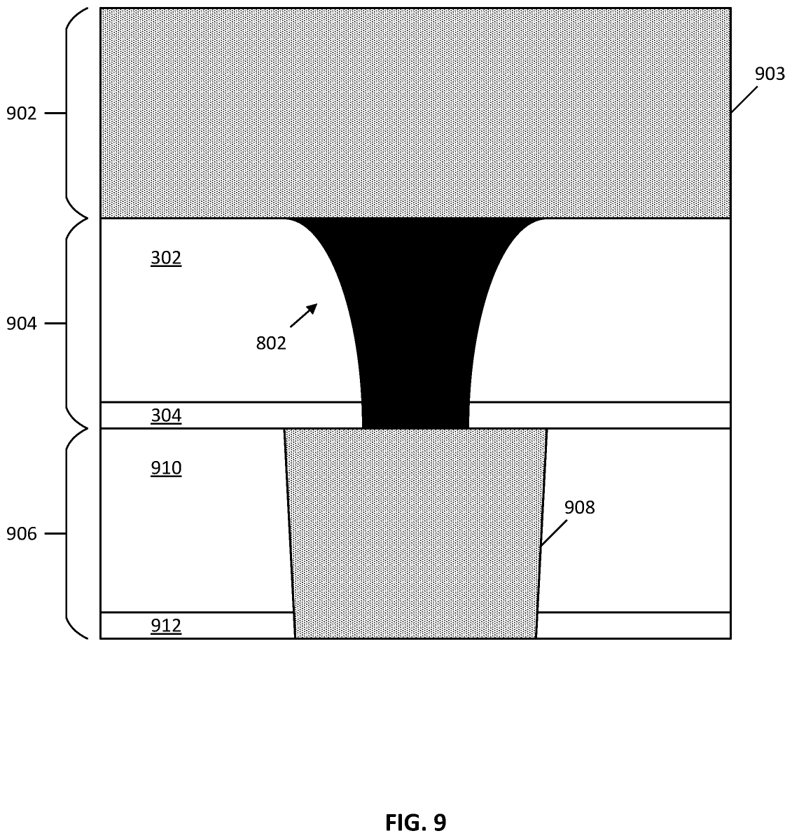

FIG. 9 illustrates a cross-section view across multiple interconnect layers to show how conductive via 802 may be situated between different metal lines, according to some embodiments. A first interconnect layer 902 may include a first metal line 903 above conductive via 802 and contacting a top surface of conductive via 802. A second interconnect layer 904 may include conductive via 802 extending through a height of at least dielectric layer 302 within second interconnect layer 904. A third interconnect layer 906 includes a second metal line 908 beneath conductive via 802 and contacting a bottom surface of conductive via 802. Third interconnect layer 906 may also include a dielectric layer 910 and an etch-stop layer 912, with second metal line 908 extending through a height of both dielectric layer 910 and etch-stop layer 912.

First metal line 903 may run lengthwise across the page while second metal line 908 may run lengthwise into and out of the page (e.g., perpendicular to first metal line 903). In this example, conductive via 802 provides electrical connection between first metal line 903 and second metal line 908. In some embodiments, second metal line 908 may be a contact directly on a given transistor element, such as a contact on a source or drain region of a transistor. The flared profile of conductive via 802 provides greater contact surface area with first metal line 903 thus decreasing the resistance through conductive via 802.

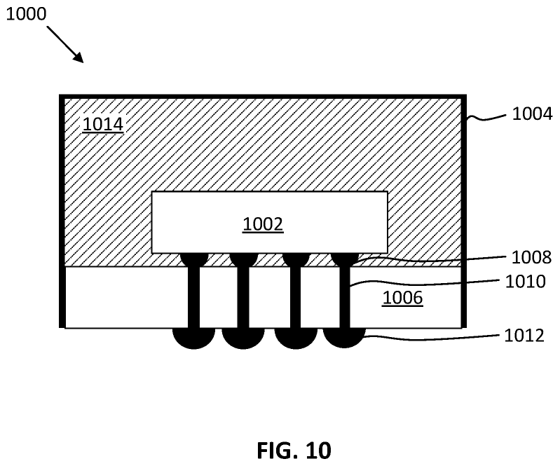

FIG. 10 illustrates an example embodiment of a chip package 1000, in accordance with an embodiment of the present disclosure. As can be seen, chip package 1000 includes one or more dies 1002. One or more dies 1002 may include at least one integrated circuit having a structure as described in any of the aforementioned embodiments. One or more dies 1002 may include any other circuitry used to interface with other devices formed on the dies, or other devices connected to chip package 1000, in some example configurations.

As can be further seen, chip package 1000 includes a housing 1004 that is bonded to a package substrate 1006. The housing 1004 may be any standard or proprietary housing, and may provide, for example, electromagnetic shielding and environmental protection for the components of chip package 1000. The one or more dies 1002 may be conductively coupled to a package substrate 1006 using connections 1008, which may be implemented with any number of standard or proprietary connection mechanisms, such as solder bumps, ball grid array (BGA), pins, or wire bonds, to name a few examples. Package substrate 1006 may be any standard or proprietary package substrate, but in some cases includes a dielectric material having conductive pathways (e.g., including conductive vias and lines) extending through the dielectric material between the faces of package substrate 1006, or between different locations on each face. In some embodiments, package substrate 1006 may have a thickness less than 1 millimeter (e.g., between 0.1 millimeters and 0.5 millimeters), although any number of package geometries can be used. Additional conductive contacts 1012 may be disposed at an opposite face of package substrate 1006 for conductively contacting, for instance, a printed circuit board (PCB). One or more vias 1010 extend through a thickness of package substrate 1006 to provide conductive pathways between one or more of connections 1008 to one or more of contacts 1012. Vias 1010 are illustrated as single straight columns through package substrate 1006 for ease of illustration, although other configurations can be used (e.g., damascene, dual damascene, through-silicon via, or an interconnect structure that meanders through the thickness of substrate 1006 to contact one or more intermediate locations therein). In still other embodiments, vias 1010 are fabricated by multiple smaller stacked vias, or are staggered at different locations across package substrate 1006. In the illustrated embodiment, contacts 1012 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1012, to inhibit shorting.

In some embodiments, a mold material 1014 may be disposed around the one or more dies 1002 included within housing 1004 (e.g., between dies 1002 and package substrate 1006 as an underfill material, as well as between dies 1002 and housing 1004 as an overfill material). Although the dimensions and qualities of the mold material 1014 can vary from one embodiment to the next, in some embodiments, a thickness of mold material 1014 is less than 1 millimeter. Example materials that may be used for mold material 1014 include epoxy mold materials, as suitable. In some cases, the mold material 1014 is thermally conductive, in addition to being electrically insulating.

### Methodology

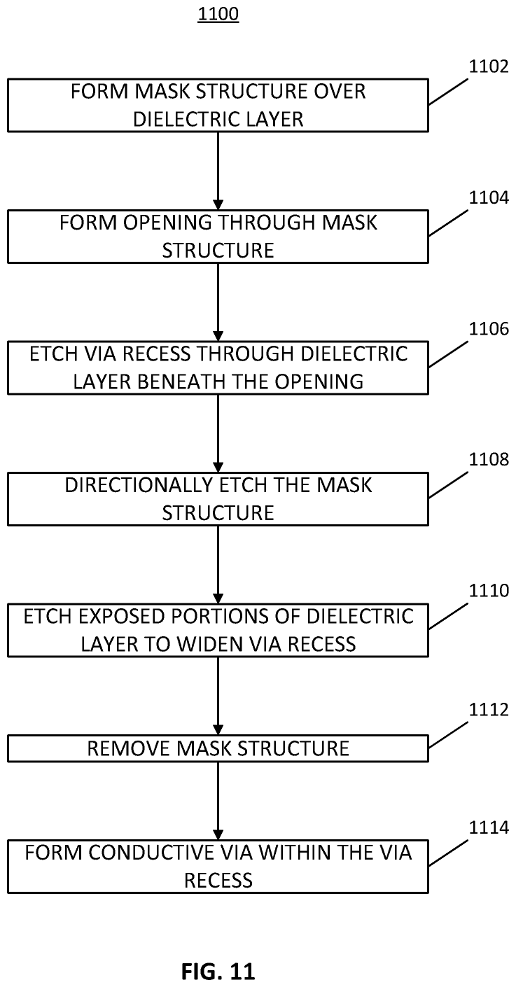

FIG. 11 is a flow chart of a method 1100 for forming at least a portion of an integrated circuit, according to an embodiment. Various operations of method 1100 may be illustrated in FIGS. 3A-8A and 3B-8B. However, the correlation of the various operations of method 1100 to the specific components illustrated in the aforementioned figures is not intended to imply any structural and/or use limitations. Rather, the aforementioned figures provide one example embodiment of method 1100. Other operations may be performed before, during, or after any of the operations of method 1100. Some of the operations of method 1100 may be performed in a different order than the illustrated order. In some embodiments, the various operations of method 1100 are performed during back end-of-the-line (BEOL) processing, although other applications may benefit from the techniques described herein, including backside interconnect structures.

Method 1100 begins with operation 1102 where a mask structure is formed over a dielectric layer of a given interconnect layer. The mask structure includes a material that can be easily removed without damaging lower material layers, and can be easily shaped using directional anisotropic etching. In some embodiments, the mask structure includes CHM. The mask structure may have a thickness between about 10 nm and about 50 nm. The dielectric layer may be any dielectric material, such as silicon oxide, silicon oxynitride, silicon nitride, or silicon oxycarbide.

Method 1100 continues with operation 1104 where an opening is formed though the mask structure to expose the underlying dielectric layer. Any suitable lithography process can be used to etch the opening through the mask structure. The etching process may use an anisotropic etching technique, such as RIE. The opening designates the location for the via that will extend through a height of the underlying dielectric layer. The size of the opening may be substantially the same across the first direction and the second direction. The opening may have a generally square or circular plan profile. The opening width may be between about 10 nm and about 20 nm.

Method 1100 continues with operation 1106 where a via recess is formed through the dielectric layer beneath the opening in the mask structure. The via recess may be formed using an anisotropic etching technique, such as RIE. The sidewalls of the via recess may be substantially straight as the aspect ratio of the via recess is close to 1:1, although the techniques described herein can be use with any number of height-to-width ratios to provide an asymmetric via. In some embodiments, the bottom of the via recess may include an etch stop layer, such that the etching process continues through the dielectric layer and terminates at the etch stop layer.

Method 1100 continues with operation 1108 where the mask structure is directionally etched using an angled RIE process. According to some embodiments, an oxygen-rich ion beam is used along with an angled electric field to drive the ions at an angle and etch away more of the mask structure along the first direction compared to the second direction. Other such directional etch schemes can be used as well. As a result, the mask structure pulls back from the edge of the via recess further along the first direction compared to the second direction. In some embodiments, the mask structure is pulled away from the via recess along the first direction by between 2 to 15 nm on each side of the via recess and is pulled away from the via recess along the second direction by an amount of less than 2 nm or less than 1 nm on each side of the via recess.

Method 1100 continues with operation 1110 where another anisotropic etch is performed to etch the further exposed portions of the dielectric layer. According to some embodiments, this etching process widens the via recess along the first direction at the top of the via recess while maintaining substantially the same width along the first direction at the bottom of the via recess. Due to the asymmetric pattern of the mask structure around the via recess, the top of the via recess is not appreciably widened across the second direction (e.g., widened by less than 2 nm or less than 1 nm). Along the first direction, the top of the via recess may be widened by as much as 10 nm, 15 nm, 20 nm, or greater. In some examples, the vertical RIE etch rounds off the exposed corners of the dielectric layer and forms gradually tapered or flared sidewalls for the etch recess. In other examples, vertical RIE etch provides more of an abrupt step-like transition in the dielectric layer. The etch process may vary between angled and vertical over a given duration to create a desired transition profile. According to some embodiments, the sidewalls flare outward further along the first direction then they do along the second direction (or there may be no notable tapering or flaring at all along the second direction). The degree of taper (or step) may vary depending on the parameters of the RIE process.

Method 1100 continues with operation 1112 where the mask structure is removed. According to some embodiments, an isotropic etching process is used to remove the mask structure. In some examples, an ashing process is used to remove a CHM structure.

Method 1100 continues with operation 1114 where a conductive via is formed within the via recess. The conductive via may be formed by depositing one or more conductive materials using any one of electroplating, electroless plating, CVD, or PECVD, to name a few examples. The conductive via may include any suitable metal material such as copper, tungsten, ruthenium, cobalt, molybdenum, or aluminum to name a few examples. In some embodiments, the conductive via includes a thin liner or barrier layer deposited first on the recess sidewalls and recess bottom followed by a metal fill on the liner. The liner may include suitable metals or compounds such as titanium nitride, titanium silicide, tungsten carbo-nitride (WCN), PVD or ALD tungsten, or tantalum nitride. The liner may have a thickness, for instance, between about 2 and 5 nm.

According to some embodiments, the conductive via includes an asymmetrically tapered profile with a longer flared taper or step along the first direction compared to the second direction due to the shape of the via recess. The bottom of the conductive via may have substantially the same contact surface area compared to a via formed using a traditional process (e.g., without inducing any flare) while the top of the conductive via has a greater contact surface due to its flared design. The greater contact surface area at the via's top surface reduces the resistance through the via while maintaining a small CD at the via's bottom surface.

### Example System

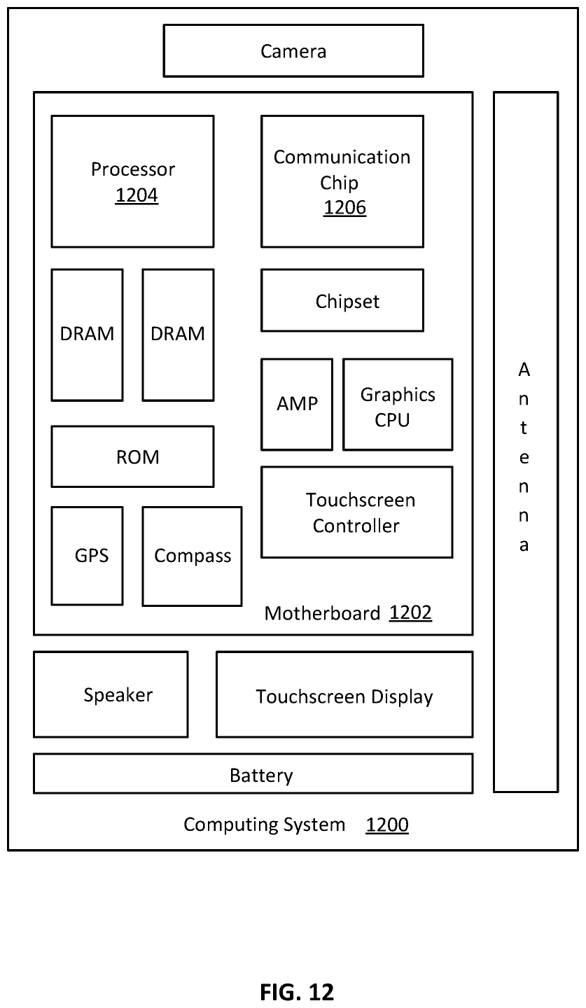

FIG. 12 is an example computing system implemented with one or more of the integrated circuit structures as disclosed herein, in accordance with some embodiments of the present disclosure. As can be seen, the computing system 1200 houses a motherboard 1202. The motherboard 1202 may include a number of components, including, but not limited to, a processor 1204 and at least one communication chip 1206, each of which can be physically and electrically coupled to the motherboard 1202, or otherwise integrated therein. As will be appreciated, the motherboard 1202 may be, for example, any printed circuit board (PCB), whether a main board, a daughterboard mounted on a main board, or the only board of system 1200, etc.

Depending on its applications, computing system 1200 may include one or more other components that may or may not be physically and electrically coupled to the motherboard 1202. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1200 may include one or more integrated circuit structures or devices configured in accordance with an example embodiment (e.g., a module including an integrated circuit having interconnect structures that have one or more asymmetrically flared vias). In some embodiments, multiple functions can be integrated into one or more chips (e.g., for instance, note that the communication chip 1206 can be part of or otherwise integrated into the processor 1204).

The communication chip 1206 enables wireless communications for the transfer of data to and from the computing system 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1206 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1200 may include a plurality of communication chips 1206. For instance, a first communication chip 1206 may be dedicated to shorter range wireless communications such as Wi-Fi and Bluetooth and a second communication chip 1206 may be dedicated to longer range wireless communications such as GPS, EDGE, GPRS, CDMA, WiMAX, LTE, Ev-DO, and others.

The processor 1204 of the computing system 1200 includes an integrated circuit die packaged within the processor 1204. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1206 also may include an integrated circuit die packaged within the communication chip 1206. In accordance with some such example embodiments, the integrated circuit die of the communication chip includes one or more semiconductor devices as variously described herein. As will be appreciated in light of this disclosure, note that multi-standard wireless capability may be integrated directly into the processor 1204 (e.g., where functionality of any chips 1206 is integrated into processor 1204, rather than having separate communication chips). Further note that processor 1204 may be a chip set having such wireless capability. In short, any number of processor 1204 and/or communication chips 1206 can be used. Likewise, any one chip or chip set can have multiple functions integrated therein.

In various implementations, the computing system 1200 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1200 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit having a plurality of semiconductor devices, an interconnect region above the plurality of semiconductor devices having a plurality of interconnect layers, and a via structure within an interconnect layer of the plurality of interconnect layers. The via structure has a first dimension across a top surface of the via structure along a first direction and a second dimension across the top surface of the via structure along a second direction orthogonal to the first direction. In some such examples, the first dimension is greater than the second dimension by at least 4 nm or 5 nm. The via structure also has a third dimension across a bottom surface of the via structure along the first direction and a fourth dimension across the bottom surface of the via structure along the second direction. The third dimension is within 1 nm of the fourth dimension.

Example 2 includes the integrated circuit of Example 1, wherein the via structure comprises a conductive liner and a conductive fill on the conductive liner.

Example 3 includes the integrated circuit of Example 2, wherein the conductive liner comprises titanium or tantalum.

Example 4 includes the integrated circuit of Example 2 or 3, wherein the conductive fill comprises tungsten, ruthenium, molybdenum, or colbalt.

Example 5 includes the integrated circuit of any one of Examples 1-4, wherein the second dimension is within 1 nm of the third dimension and the fourth dimension.

Example 6 includes the integrated circuit of any one of Examples 1-5, wherein the third dimension is between about 15 nm and about 20 nm and the fourth dimension is between about 15 nm and about 20 nm.

Example 7 includes the integrated circuit of Example 6, wherein the first dimension is between about 15 nm and about 20 nm and the second dimension is between about 20 nm and about 30 nm.

Example 8 includes the integrated circuit of any one of Examples 1-7, wherein a cross-section of the via structure across a plane parallel to the first direction and parallel to a third direction perpendicular to both the first direction and the second direction includes sidewalls having a tapered profile between the top surface of the via structure and the bottom surface of the via structure.

Example 9 includes the integrated circuit of Example 8, wherein a cross-section of the via structure across a plane parallel to the second direction and parallel to the third direction includes sidewalls having a substantially straight profile between the top surface of the via structure and the bottom surface of the via structure.

Example 10 includes the integrated circuit of Example 8, wherein a cross-section of the via structure across a plane parallel to the second direction and parallel to the third direction includes sidewalls having a tapered profile between the top surface of the via structure and the bottom surface of the via structure.

Example 11 includes the integrated circuit of any one of Examples 1-7, wherein a cross-section of the via structure across a plane parallel to the first direction and parallel to a third direction perpendicular to both the first direction and the second direction includes sidewalls having a step profile between the top surface of the via structure and the bottom surface of the via structure.

Example 12 includes the integrated circuit of Example 11, wherein a cross-section of the via structure across a plane parallel to the second direction and parallel to the third direction includes sidewalls having a substantially straight profile between the top surface of the via structure and the bottom surface of the via structure.

Example 13 includes the integrated circuit of Example 11, wherein a cross-section of the via structure across a plane parallel to the second direction and parallel to the third direction includes sidewalls having a step profile between the top surface of the via structure and the bottom surface of the via structure.

Example 14 is a printed circuit board that includes the integrated circuit of any one of Examples 1-13.

Example 15 is an integrated circuit that includes an interconnect region above a plurality of semiconductor devices with the interconnect region having a plurality of interconnect layers, and an interconnect layer of the plurality of interconnect layers. The interconnect layer includes a dielectric layer and a via passing through the dielectric layer. The via has a first dimension across a top surface of the via along a first direction and a second dimension across the top surface of the via along a second direction orthogonal to the first direction. The first dimension is greater than the second dimension by at least 4 nm or 5 nm. The via also has a third dimension across a bottom surface of the via along the first direction and a fourth dimension across the bottom surface of the via along the second direction. The third dimension is within 1 nm of the fourth dimension.

Example 16 includes the integrated circuit of Example 15, wherein the via comprises a conductive liner and a conductive fill on the conductive liner.

Example 17 includes the integrated circuit of Example 16, wherein the conductive liner comprises titanium or tantalum.

Example 18 includes the integrated circuit of Example 16 or 17, wherein the conductive fill comprises tungsten, ruthenium, molybdenum, or colbalt.

Example 19 includes the integrated circuit of any one of Examples 15-18, wherein the second dimension is within 1 nm of the third dimension and the fourth dimension.

Example 20 includes the integrated circuit of any one of Examples 15-19, wherein the third dimension is between about 15 nm and about 20 nm and the fourth dimension is between about 15 nm and about 20 nm.

Example 21 includes the integrated circuit of Example 20, wherein the first dimension is between about 15 nm and about 20 nm and the second dimension is between about 20 nm and about 30 nm.

Example 22 includes the integrated circuit of any one of Examples 15-21, wherein a cross-section of the via structure across a plane parallel to the first direction and parallel to a third direction perpendicular to both the first direction and the second direction includes sidewalls having a tapered profile between the top surface of the via and the bottom surface of the via.

Example 23 includes the integrated circuit of Example 22, wherein a cross-section of the via across a plane parallel to the second direction and parallel to the third direction includes sidewalls having a substantially straight profile between the top surface of the via and the bottom surface of the via.

Example 24 is a printed circuit board that includes the integrated circuit of any one of Examples 15-23.

Example 25 is a method of forming an integrated circuit. The method includes forming an interconnect layer above a plurality of semiconductor devices. Forming the interconnect layer includes forming a dielectric layer, forming an opening through the dielectric layer, and forming a conductive via within the opening. Forming the opening includes forming a mask material on the dielectric layer, etching a first opening through the mask material, etching a second opening through the dielectric layer beneath the first opening, directionally etching the mask material to remove portions of the mask material along opposing edges of the opening through the dielectric layer, etching exposed portions of the dielectric layer beneath the removed portions of the mask material, and removing any remaining portion of the mask material.

Example 26 includes the method of Example 25, wherein forming the conductive via comprises forming a conductive liner within the opening through the dielectric layer, and forming a conductive fill on the conductive liner.

Example 27 is an electronic device that includes a chip package having one or more dies. At least one of the one or more dies includes a plurality of semiconductor devices, an interconnect region above the plurality of semiconductor devices and having a plurality of interconnect layers, and a via structure within an interconnect layer of the interconnect layers. The via structure has a first dimension across a top surface of the via structure along a first direction and a second dimension across the top surface of the via structure along a second direction orthogonal to the first direction with the first dimension being greater than the second dimension by at least 5 nm. The via structure has a third dimension across a bottom surface of the via structure along the first direction and a fourth dimension across the bottom surface of the via structure along the second direction with the third dimension being within 1 nm of the fourth dimension.

Example 28 includes the electronic device of Example 27, wherein the via structure comprises a conductive liner and a conductive fill on the conductive liner.

Example 29 includes the electronic device of Example 28, wherein the conductive liner comprises titanium or tantalum.

Example 30 includes the electronic device of Example 28 or 29, wherein the conductive fill comprises tungsten, ruthenium, molybdenum, or colbalt.

Example 31 includes the electronic device of any one of Examples 27-30, wherein the second dimension is within 1 nm of the third dimension and the fourth dimension.

Example 32 includes the electronic device of any one of Examples 27-31, wherein the third dimension is between about 15 nm and about 20 nm and the fourth dimension is between about 15 nm and about 20 nm.

Example 33 includes the electronic device of Example 32, wherein the first dimension is between about 15 nm and about 20 nm and the second dimension is between about 20 nm and about 30 nm.

Example 34 includes the electronic device of any one of Examples 27-33, wherein a cross-section of the via structure across a plane parallel to the first direction and parallel to a third direction perpendicular to both the first direction and the second direction includes sidewalls having a tapered profile between the top surface of the via structure and the bottom surface of the via structure.

Example 35 includes the electronic device of Example 34, wherein a cross-section of the via structure across a plane parallel to the second direction and parallel to the third direction includes sidewalls having a substantially straight profile between the top surface of the via structure and the bottom surface of the via structure.

Example 36 includes the electronic device of any one of Examples 27-35, further comprising a printed circuit board, wherein the chip package is attached to the printed circuit board.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit, comprising:
a plurality of semiconductor devices;
an interconnect region above the plurality of semiconductor devices, the interconnect region comprising a plurality of interconnect layers; and
a via structure within an interconnect layer of the interconnect layers,
wherein the via structure has a first dimension across a top surface of the via structure along a first direction and a second dimension across the top surface of the via structure along a second direction orthogonal to the first direction, the first dimension being greater than the second dimension by at least 4 nm, and
wherein the via structure has a third dimension across a bottom surface of the via structure along the first direction and a fourth dimension across the bottom surface of the via structure along the second direction, the third dimension being within 1 nm of the fourth dimension.

2. The integrated circuit of claim 1, wherein the second dimension is within 1 nm of the third dimension and the fourth dimension.

3. The integrated circuit of claim 1, wherein the third dimension is between about 15 nm and about 20 nm and the fourth dimension is between about 15 nm and about 20 nm.

4. The integrated circuit of claim 3, wherein the first dimension is between about 15 nm and about 20 nm and the second dimension is between about 20 nm and about 30 nm.

5. The integrated circuit of claim 1, wherein a cross-section of the via structure across a plane parallel to the first direction and parallel to a third direction perpendicular to both the first direction and the second direction includes sidewalls having a tapered profile between the top surface of the via structure and the bottom surface of the via structure.

6. The integrated circuit of claim 5, wherein a cross-section of the via structure across a plane parallel to the second direction and parallel to the third direction includes sidewalls having a substantially straight profile between the top surface of the via structure and the bottom surface of the via structure.

7. The integrated circuit of claim 1, wherein a cross-section of the via structure across a plane parallel to the first direction and parallel to a third direction perpendicular to both the first direction and the second direction includes sidewalls having a step profile between the top surface of the via structure and the bottom surface of the via structure.

8. The integrated circuit of claim 7, wherein a cross-section of the via structure across a plane parallel to the second direction and parallel to the third direction includes sidewalls having a substantially straight profile between the top surface of the via structure and the bottom surface of the via structure.

9. A printed circuit board comprising the integrated circuit of claim 1.

10. An integrated circuit, comprising:
an interconnect region above a plurality of semiconductor devices, the interconnect region comprising a plurality of interconnect layers; and
an interconnect layer of the plurality of interconnect layers, the interconnect layer comprising a dielectric layer and a via passing through the dielectric layer,
wherein the via has a first dimension across a top surface of the via along a first direction and a second dimension across the top surface of the via along a second direction orthogonal to the first direction, the first dimension being greater than the second dimension by at least 5 nm, and
wherein the via has a third dimension across a bottom surface of the via along the first direction and a fourth dimension across the bottom surface of the via along the second direction, the third dimension being within 1 nm of the fourth dimension.

11. The integrated circuit of claim 10, wherein the second dimension is within 1 nm of the third dimension and the fourth dimension.

12. The integrated circuit of claim 10, wherein the first dimension is between about 15 nm and about 20 nm and the second dimension is between about 20 nm and about 30 nm.

13. The integrated circuit of claim 10, wherein a cross-section of the via across a plane parallel to the first direction and parallel to a third direction perpendicular to both the first direction and the second direction includes sidewalls having a tapered profile between the top surface of the via and the bottom surface of the via.

14. The integrated circuit of claim 13, wherein a cross-section of the via across a plane parallel to the second direction and parallel to the third direction includes sidewalls having a substantially straight profile between the top surface of the via and the bottom surface of the via.

15. An electronic device, comprising:
a chip package comprising one or more dies, at least one of the one or more dies comprising
a plurality of semiconductor devices;
an interconnect region above the plurality of semiconductor devices, the interconnect region comprising a plurality of interconnect layers; and
a via structure within an interconnect layer of the interconnect layers,
wherein the via structure has a first dimension across a top surface of the via structure along a first direction and a second dimension across the top surface of the via structure along a second direction orthogonal to the first direction, the first dimension being greater than the second dimension by at least 5 nm, and
wherein the via structure has a third dimension across a bottom surface of the via structure along the first direction and a fourth dimension across the bottom surface of the via structure along the second direction, the third dimension being within 1 nm of the fourth dimension.

16. The electronic device of claim 15, wherein the second dimension is within 1 nm of the third dimension and the fourth dimension.

17. The electronic device of claim 15, wherein the first dimension is between about 15 nm and about 20 nm and the second dimension is between about 20 nm and about 30 nm.

18. The electronic device of claim 15, wherein a cross-section of the via structure across a plane parallel to the first direction and parallel to a third direction perpendicular to both the first direction and the second direction includes sidewalls having a tapered profile between the top surface of the via structure and the bottom surface of the via structure.

19. The electronic device of claim 18, wherein a cross-section of the via structure across a plane parallel to the second direction and parallel to the third direction includes sidewalls having a substantially straight profile between the top surface of the via structure and the bottom surface of the via structure.

20. The electronic device of claim 15, further comprising a printed circuit board, wherein the chip package is attached to the printed circuit board.
